(19) United States
(12) Patent Application Publication
(10) Pub. No.: US 2008/0173864 A1
(43) Pub. Date: Jul. 24, 2008

(54) CARBON NANOTUBE TRANSISTOR HAVING LOW FRINGE CAPACITANCE AND LOW CHANNEL RESISTANCE

(75) Inventors: Shinobu Fujita, Palo Alto, CA (US); Bipul C. Paul, Sunnyvale, CA (US)

Correspondence Address: WATCHSTONE P+D, PLC, 1250 CONNECTICUT AVENUE, N.W., SUITE 700, WASHINGTON, DC, 20036-2657, US

(73) Assignee: TOSHIBA AMERICA RESEARCH, INC.

(21) Appl. No.: 11/625,307

(22) Filed: Jan. 20, 2007

(51) Int. Cl. H01L 51/30

(52) U.S. Cl. 257/40; 257/E51.04

(57) ABSTRACT

A CNT transistor has source extension 36a and drain extension 36b that shunt electrical current and reduce the effective CNT resistance and allow significant reductions in fringe capacitances 28 30. The extensions 36a 36b are electrically conductive, and are electrically connected to the source electrode 22 and drain electrode 24. The extensions each span a portion of gaps 35a 35b. Consequently, the source and drain can be located relatively far from the gate electrode 26, thereby reducing the fringe capacitances 28 30. Nanotube 20 is a semiconducting single-walled carbon nanotube, and the extensions 36a 36b comprise metallic-conducting nanotubes surrounding and coaxial with the nanotube 20. The nanotube 20 and extensions 36a 36b are fabricated from a multiwalled nanotube by selectively removing outer nanotubes in a region near the gate electrode. Alternatively, the extensions 36a 36b can comprise metal deposited on peripheral portions of the semiconducting CNT 20.

### FIELD OF THE INVENTION

The present invention relates generally to nanoscale electronic devices. More particularly, the preferred embodiments relate to a carbon nanotube transistor in which portions of the CNT close to source and drain electrodes are coated with a highly conductive material (e.g. metallic-conducting nanotubes). The conductive material reduces the electrical resistance of the nanotube transistor.

### BACKGROUND

In recent years, nanoscale transistors made of carbon nanotubes (CNTs) have attracted intense interest. CNT transistors have the potential to dramatically reduce the size, cost and operating power of electronic devices. An exemplary conventional CNT transistor is illustrated in FIG. 1. The transistor has a carbon nanotube 20 electrically connected between source electrode 22 and drain electrode 24. A gate electrode 26 disposed over the CNT controls the flow of current through the CNT. A gate insulation layer 27 (e.g. comprising SiO2) is disposed between the CNT 20 and the gate electrode. The CNT can be a single walled semiconducting nanotube (SWNT). The source, drain, and gate can comprise metal or doped polysilicon, for example.

The performance of the CNT transistor is strongly affected by a gate-source fringe capacitance 28 and a drain-gate fringe capacitance 30. These fringe capacitances 28 30 reduce the switching speed of the transistor, which of course is undesirable. The fringe capacitances 28 30 depend greatly upon the shapes of the gate, source and drain electrodes, and the spacing between them. In CNT transistor devices, the fringe capacitances tend to be very large because the gate, source and drain are located very close together. For example, even though carbon nanotubes have intrinsically higher electron and hole mobilities than silicon, the electrical performance of carbon nanotube transistors tends to be worse than silicon transistors because of the fringe capacitances 28 30. Hence, for CNT transistors to have superior performance compared to silicon devices (a benchmark for economic viability), the fringe capacitances must be reduced.

Another problem with the device of FIG. 1 is that the CNT 20 has a relatively high resistance in gap areas 32 where it is not covered by the gate electrode 26. High resistance in the gap areas 32 also tends to reduce the switching speed of the transistor. The resistance of the CNT 20 is decreased by decreasing the width of the gaps 32. However, this also tends to increase the fringe capacitance. Hence, there exists a performance tradeoff between fringe capacitance and CNT resistance that prevents further improvement in transistor speed and performance. In fact, the switching speed tends to be inversely proportional to an RC time constant largely determined by the fringe capacitance and nanotube resistance.

It would be an advance in the art of CNT transistors and nanoscale electronic devices to provide a CNT transistor structure that avoids the described tradeoffs between fringe capacitance and CNT resistance. Such a device could have very low values of both fringe capacitance and CNT resistance, and therefore exceptionally fast switching speeds and high performance generally. Such a device could exceed the performance characteristics of silicon transistors.

### SUMMARY

The preferred embodiments of the present invention provide a carbon nanotube (CNT) transistor having source and drain electrodes, and a semiconducting CNT connected between the source and drain. A gate electrode is disposed proximate to the semiconducting CNT, for modulating the resistance thereof. The gate is spaced apart from the source and drain; the source and gate define a first gap, and the drain and gate define a second gap. The semiconducting CNT spans both gaps. Significantly, in the present invention, the transistor has a source extension extending from the source, and/or a drain extension extending from the drain. The extensions span at least a portion of the gaps (e.g. at least ½ way across the gaps). The extensions are electrically conductive, and tend to shunt current away from the semiconducting CNT. The extensions reduce the source-drain resistance of the present transistor, and allow the source and drain to be spaced far from the gate thereby decreasing the fringe capacitance.

The extensions preferably comprise metallic conductive carbon nanotube surrounding and coaxial with the semiconducting CNT. The semiconducting CNT comprises a single-walled carbon nanotube (SWNT); the extensions can comprise 1-30 nanotubes coaxial with the semiconducting CNT, for example.

The extensions can also comprise deposited metal, such as copper, aluminum or the like.

Preferably, the extensions are narrow in a direction perpendicular to the semiconducting CNT (i.e. the Y-direction, see FIG. 2). For example, the extensions can be less than 2 times or 5 times the width of the semiconducting CNT.

The above and/or other aspects, features and/or advantages of various embodiments will be further appreciated in view of the following description in conjunction with the accompanying figures. Various embodiments can include and/or exclude different aspects, features and/or advantages where applicable. In addition, various embodiments can combine one or more aspect or feature of other embodiments where applicable. The descriptions of aspects, features and/or advantages of particular embodiments should not be construed as limiting other embodiments or the claims.

### BRIEF DESCRIPTION OF THE FIGURES

The preferred embodiments of the present invention are shown by a way of example, and not limitation in the accompanying figures, in which:

FIG. 1 (Prior Art) shows a perspective view of a conventional CNT transistor, wherein the device of FIG. 1 has relatively high values of fringe capacitance and source-drain resistance, and therefore slow operating speed;

FIG. 2 shows a perspective view of the present CNT transistor according to some embodiments;

FIG. 3 shows a cross sectional view of the CNT transistor of FIG. 2, cut along the dotted line collinear with the CNT;

FIG. 4a-4d illustrate a preferred method for fabricating the CNT transistor from a multiwalled carbon nanotube;

FIGS. 5a-5e illustrate a method for fabricating the CNT transistor with extensions made of metal; and

FIG. 6 shows a top view of a CNT transistor having four nanotubes connected in parallel between source and drain.

### DETAILED DESCRIPTION OF THE PREFERRED EMBODIMENTS

While the present invention may be embodied in many different forms, a number of illustrative embodiments are described herein with the understanding that the present disclosure is to be considered as providing examples of the principles of the invention and that such examples are not intended to limit the invention to preferred embodiments described herein and/or illustrated herein.

In relation to the preferred embodiments the following terminology is employed.

Carbon nanotube (CNT): An approximately 1-dimensional nanostructure comprising one or more coaxial graphite tubes. Carbon nanotubes in the present invention can have diameters of about 1-100 nanometers, and 1-50 graphite layers. The diameter and number of graphite layers of the carbon nanotube may vary over its length. Also, a carbon nanotube in the present transistor structure may comprise a plurality or many parallel (i.e., non-coaxial) carbon nanotubes (i.e., a nanotube ‘rope’).

The preferred embodiments of the present invention provide a CNT transistor with relatively low values of fringe capacitance (i.e., gate-source capacitance, and gate-drain capacitance) and source-drain resistance (i.e., CNT resistance). The present transistor structure has source and drain electrodes and a semiconducting CNT connected between the source and drain. A gate is disposed close to the CNT and controls the resistance of the CNT, as known in the art. In the preferred present transistor structure, there is a gap between the gate and source and a gap between the gate and drain. The CNT spans both gaps. In the gap regions, the CNT is covered with conductive extensions (e.g. additional carbon nanotubes) extending from the source or drain (a source extension and a drain extension). The source and drain extensions shunt electrical current and thereby reduce the electrical resistance of the CNT in the gap region, without significantly increasing the fringe capacitance. Hence, the present CNT transistor structure has exceptionally low values of both fringe capacitance and electrical resistance.

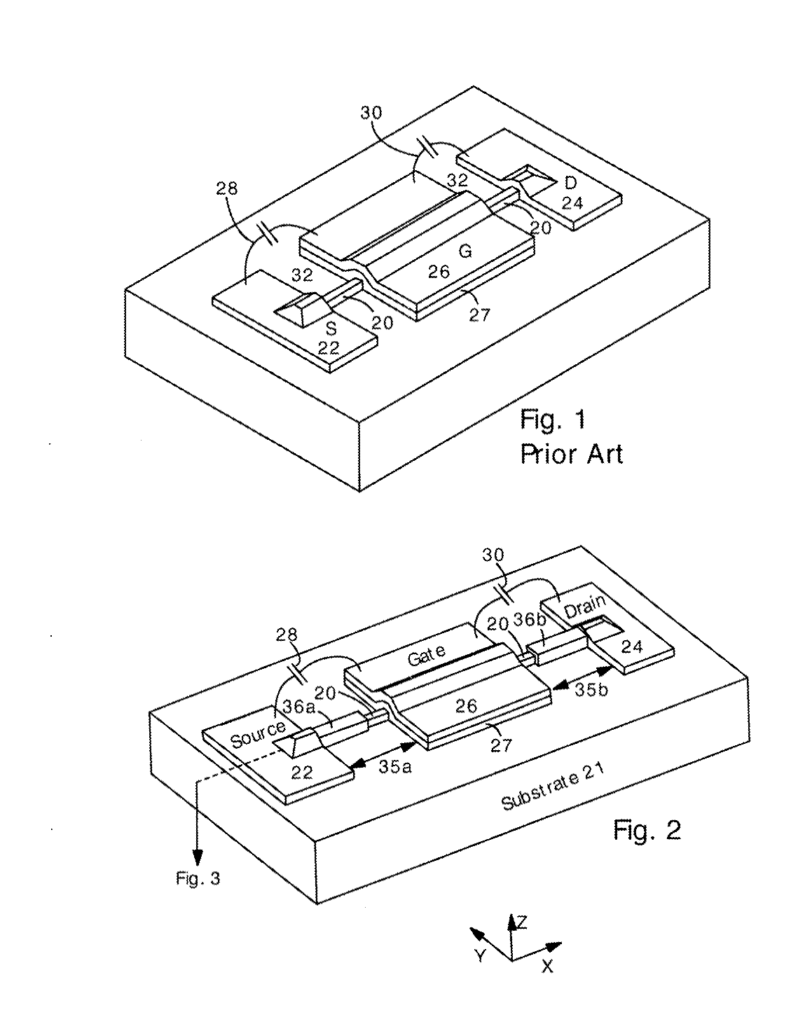

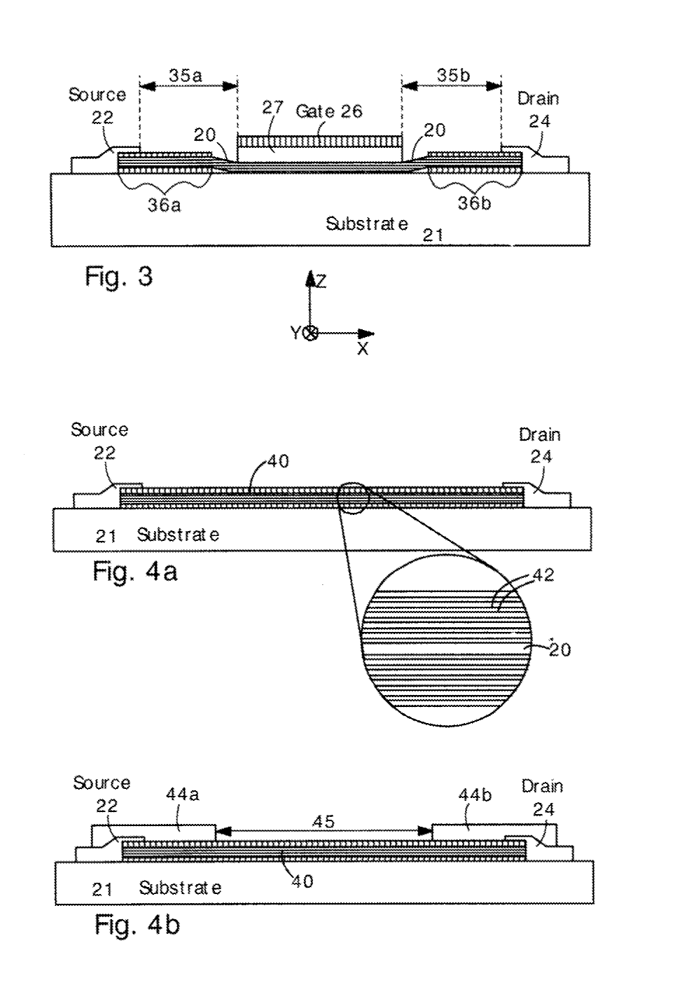

FIG. 2 shows a perspective view of the present CNT transistor structure, and FIG. 3 shows a cross sectional view of the transistor structure. The transistor has a semiconducting CNT 20, a source electrode 22, a drain electrode 24, gate electrode 26, and gate insulator 27. Fringe capacitances 28 30 exist between the source, gate and drain electrodes, and tend to reduce the maximum operating speed of the device. However, in the present transistor design, the fringe capacitances 28 30 have a lower value compared to a CNT transistor of the prior art, illustrated in FIG. 1. The transistor is fabricated on a substrate 21, which can be made of silicon, sapphire, ceramic or any other suitable substrate material.

In the preferred present transistor structure, a first gap 35a and a second gap 35b are relatively large (compared to similar prior art devices), which provides low fringe capacitance 28 30 values. For example, the gaps can be about 0.1 microns or less wide (in the X-direction). Significantly, in the present invention, a source extension 36a extends from the source 22 and covers a portion of the CNT 20 in the first gap 35a; also, a drain extension 36b extends from the drain 24 and covers a portion of the CNT 20 in the second gap 35b. The extensions 36a 36b are electrically conductive and electrically connected to the source and drain, respectively.

The extensions 36a 36b are made of a highly conductive material such as metallic carbon nanotubes, or sputtered or electroplated metal such as Ti, W, or Pt. In a preferred embodiment, the extensions 36a 36b comprise multi-walled carbon nanotubes surrounding and coaxial with the semiconducting CNT 20. In other words, the semiconducting CNT 20 can be a central single-walled nanotube extending from the center of the extensions 36a 36b. The CNT 20 can be a single-walled nanotube that is highly doped with N-type dopant or P-type dopant so that contact between the extension 36a/36b and the CNT 20 is ohmic contact. In this case, the semiconducting CNT 20 has fewer numbers of walls of nanotubes than the extensions 36a 36b. Since the extensions 36a 36b are metal and the CNT 20 is semiconductor, the extensions 36a 36b have a resistance per unit length much lower than the CNT 20. For example, the extensions 36a 36b can have a resistance per unit length less than 1/50, 1/100, or 1/500 the resistance per unit length of the CNT 20. For example, each extension 36a 36b can have a resistance of about 50-500 ohms, and the semiconducting CNT (between the extensions) can have a resistance of about 10 k-30 k ohms.

The extensions 36a 36b at least partially cover the CNT in the gaps 35a 35b. Preferably, the extensions 36a 36b are at least ¼, ½ or ⅔ as long as the width of the gaps 35a 35b. The extensions 36a 36b can extend the full length of the gaps 35a 35b, provided that the extensions do not touch the gate electrode 26. However, making the extensions very close to the gate electrode may increase the fringe capacitance to undesirable levels. Even with the source and drain extensions 36a 36b, there still exists a tradeoff between fringe capacitance and CNT resistance, though the tradeoff is relaxed compared to transistors of the prior art.

The extensions are necessarily limited in width (i.e., in the Y-direction). Preferably, the extensions 36a 36b are less than 2, 5 or 10 times the width of the CNT 20. Increasing the extension width (in the Y-direction) tends to increase the fringe capacitances 28 30; decreasing the extension width tends to decrease the fringe capacitances 28 30. For example, if the extensions 36a 36b are as wide as the source and drain, then no reduction in fringe capacitance is provided by the extensions 36a 36b. Hence, it is preferable for the extensions 36a 36b to have a width of less than ½, ¼, 1/10 a width (in the Y-direction) of the source 22 or drain 24. Generally, the extensions 36a 36b should be as narrow (in the Y-direction) as possible.

In operation, the conductivity of the semiconducting CNT 20 is controlled by voltage applied to the gate electrode 26 as known in the art. Current flowing between the source and drain is shunted through the extensions 36a 36b, which will typically have a resistance lower than the CNT 20. Also, the fringe capacitance is greatly reduced because the extensions 36a 36b are very narrow in the Y-direction. Hence, the present CNT transistor structure has exceptionally low values of both fringe capacitance and resistance.

It is noted that the substrate can be used as the back gate electrode, as known in the art.

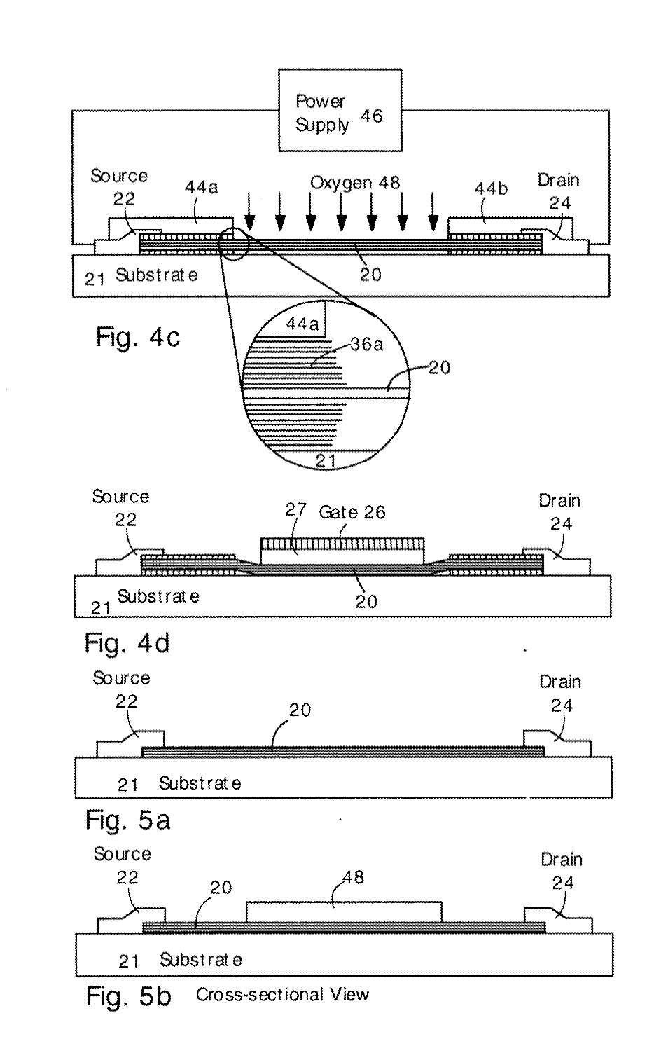

FIGS. 4a-4d illustrate a preferred method for making the present CNT transistor starting with a multi-walled carbon nanotube. The fabrication steps proceed as follows:

FIG. 4a: A multiwalled carbon nanotube 40 is disposed on a substrate surface. The substrate can comprise a silicon wafer, with an oxide or nitride coating, for example. Source 22 and drain 24 electrodes are fabricated, and the multiwalled nanotube is electrically connected between the source and drain. The source and drain can be made of sputtered or electroplated metal, for example. The multi-walled nanotube can be embedded in the source and drain, for example.

The multiwalled nanotube 40 can have 2-30 or more coaxial carbon nanotubes surrounding the central semiconducting CNT 20, for example. Typically, the multiwalled nanotube 40 will be made by a catalytic process, or by carbon arc discharge, as known in the art. The multiwalled nanotube can be deposited on the substrate by a solvent carrier, catalytically grown on the substrate or other methods known in the art.

FIG. 4a also shows a magnified view of the multi-walled carbon nanotube, illustrating individual graphitic tubes 42. The central semiconducting CNT 20 (an SWNT) is also indicated.

FIG. 4b: A mask 44a 44b is deposited and pattered. The size of the mask 44a 44b determines the length of the extensions 36a 36b. A central portion 45 of the multiwalled carbon nanotube 40 is exposed. The mask can be made of any conventional mask material, including photoresist and hard mask materials such as SiO2 or metals. Hard mask materials may better tolerate the high temperatures produced in the following ohmic heating step.

FIG. 4c: The source 22 and drain 24 electrodes are connected to an electrical power supply 46, which flows current through the multiwalled nanotube 40. Simultaneously, the multiwalled nanotube is exposed to an oxygen atmosphere 48. The atmosphere can comprise pure oxygen, or oxygen mixed with other gases. Current from the power supply 46 creates a resistive heating effect in the multiwalled nanotube 40, causing the outermost tubes of the multiwalled nanotube to become oxidized by the oxygen atmosphere. With time, the outer tubes of the original multiwalled nanotube are peeled away one by one like layers of an onion. Typically, the multiwalled nanotube 40 can have about 5-30 concentric nanotubes.

Preferably, the power supply 46 provides an approximately constant voltage. The constant voltage is selected to provide adequate current for ohmic heating and oxidation of metallic-conducting nanotubes, but insufficient current for ohmic heating and oxidation of semiconducting nanotubes. It is noted that in multiwalled carbon nanotubes, the larger-diameter, outer nanotubes are almost always metallic conductors. Hence, the outer nanotubes are most susceptible to ohmic heating and consequent oxidation. The innermost single nanotube 20 is much more likely to be semiconducting and therefore it will not be heated by the constant voltage provided by the power supply 46. In some multiwalled nanotubes, one or more outer tubes will be semiconducting. In this case, the undesired semiconducting nanotubes can be oxidized and removed by temporarily increasing the applied voltage from the power supply 46.

The magnified inset in FIG. 4c shows the eroded edges of the carbon tubes, which are aligned with an edge of the mask 44a. The unoxidized nanotubes under the mask 44a comprise the source extension 36a. Similarly, unoxidized nanotubes under the mask 44b comprise the drain extension 36b. The remaining, unoxidized nanotube 20 is a single-walled, semiconducting carbon nanotube.

If the central carbon nanotube happens to have metallic conducting properties, then it will be ohmically heated, oxidized, destroyed and entirely removed. In this case, there will be no electrical connection between the source 22 and drain 24 electrodes (unless multiple parallel nanotubes are provided). This is a desirable effect because metallic nanotubes are inoperable in a CNT transistor. However, if only a single nanotube is present, the transistor will be inoperable in this case. For this reason, it will be preferred for each transistor to have multiple nanotubes connected in parallel. If one nanotube happens to have a metallic conducting central nanotube then the other, parallel semiconducting nanotubes will remain.

The resistance of the multiwalled nanotube 40 should be monitored during heating. A sudden step-like increase in resistance indicate the destruction of the outermost carbon nanotube.

The above-described process of diameter-reduction of multiwalled carbon nanotubes by ohmic heating in an oxygen atmosphere is further explained in “Engineering Carbon Nanotubes and Nanotube Circuits Using Electrical Breakdown” by P. Collins et al., Science, Vol. 292, 27 Apr. 2001, pp. 706-709, which is hereby incorporated by reference in its entirety.

FIG. 4d: The mask 44a 44b is removed. The gate insulator 27 and gate electrode 26 are deposited on top of the CNT 20 by deposition, etching and masking steps as known in the art. The nanotube will typically bend toward the substrate (as shown) and adhere to the substrate by Van der Waals forces.

It is noted that the present nanotube transistor can have one (as illustrated) or a plurality of nanotubes (arranged in parallel) connected between the source and drain electrodes. The fabrication process for transistors having a plurality of nanotubes is the same as the process illustrated in FIGS. 4a-4d. Current is simultaneously flowed through the plurality of nanotubes while they are exposed to an oxygen atmosphere. If one carbon nanotube happens to have a metallic central nanotube, then it will be removed by the applied voltage from the power supply 46, and hence it will not produce a short circuit in the transistor. Therefore, the above diameter-reduction technique will necessarily remove central CNTs that are metallic conductors.

Alternatively, oxidizing gases other than oxygen can be used to remove the outer carbon nanotubes. For example, chlorine, fluorine, water vapor or other gases known to remove the outer carbon nanotubes can be used.

In an alternative embodiment, the extensions comprise deposited metal (e.g., electrodeposited or sputtered metal). In this case, the metal may be disposed only on a top surface of the semiconducting carbon nanotube.

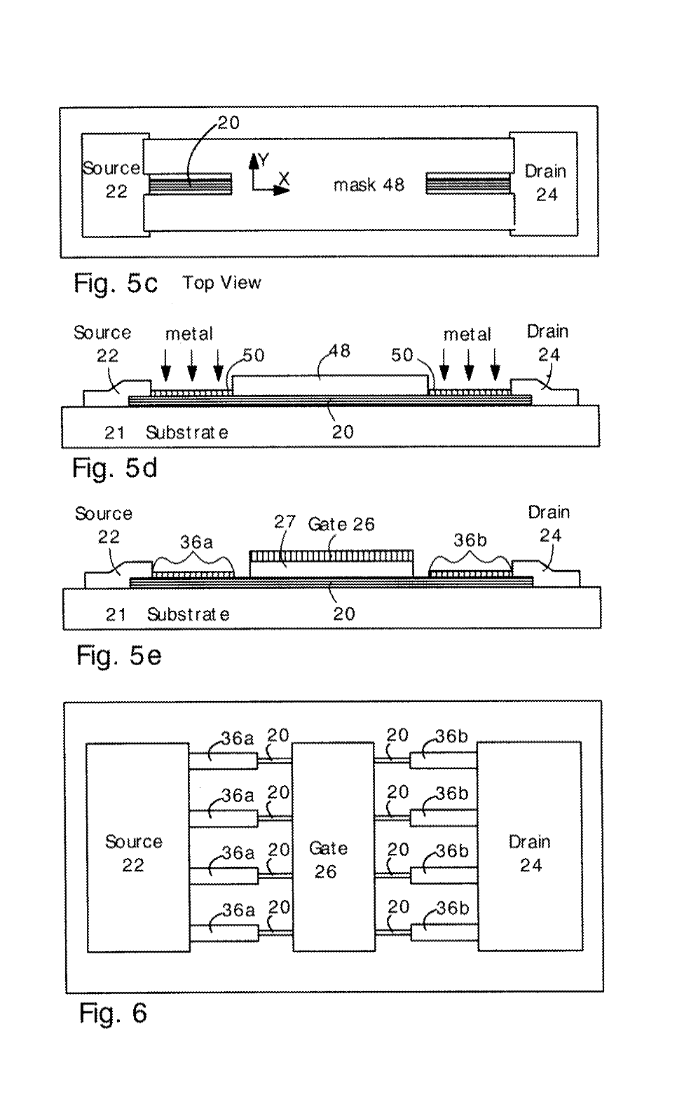

The present nanotube transistor can also be fabricated by depositing metal to form the extensions 36a 36b. FIGS. 5a-5e illustrate a preferred method for making a nanotube transistor with extensions comprising deposited metal. The fabrication steps proceed as follows:

FIG. 5a: The semiconducting CNT 20 is deposited on the substrate 21. Source 22 and drain 24 electrodes are deposited and electrically connected to the CNT 20. The CNT 20 can be catalytically grown on the substrate 21 or can be grown elsewhere and transferred to the substrate (e.g., in a solvent carrier). The semiconducting CNT 20 is a single-walled carbon nanotube.

FIG. 5b/5c: FIGS. 5b and 5c show cross sectional and top vies of the same step. A central portion of the CNT 20 is covered with a mask 48. The mask 48 is slightly wider than the gate electrode 26. The mask 48 can be made of any known masking material such as photoresist.

FIG. 5d: Metal 50 is deposited on the semiconducting CNT 20 in regions where extensions 36a 36b are desired. For example, the metal can be deposited by sputtering, chemical vapor deposition, electrodeposition or other deposition processes. In some embodiments, the metal can be Ti, W, Ni, Co, Cr, Ta, V, Fe, Al, Cu, Pt or alloys thereof for example. Preferably, the mask 48 is shaped so that the metal is deposited in a region having a very limited width (in the Y-direction). This aspect is illustrated in the top view of FIG. 5c. If the metal is electrodeposited, then it will only deposit on exposed portions of the CNT 20.

Optionally after removing mask 40 the substrate is heated at several hundred degrees C. The CNT 20 deposited with metal is thereby changed to metal carbide that is very stable and durable. The metal outside the metal carbide can be chemically removed (ex. by HF solution) so that the extension is composed of only metal carbide. Conversion to metal carbide will thereby assure that the extensions are limited in width.

FIG. 5e: The mask 48 is removed. The gate insulator 27 and gate electrode 26 are deposited on top of the CNT 20 by deposition, etching and masking steps as known in the art. The extensions 36a 36b comprise the deposited metal.

The preferred embodiments of the present invention provide a carbon nanotube transistor having reduced fringe capacitance and reduced “channel” resistance compared to the prior art. The extensions 36a 36b reduce the source-drain resistance of the transistor and simultaneously reduce the fringe capacitance. Of course, greater reductions in source-drain resistance can be achieved by tolerating a larger fringe capacitance, and vice-versa.

The preferred present transistor structure can be used in a wide range of microelectronic circuits and devices, such as memory circuits, microprocessors and the like. In such devices, similar multiwalled nanotubes can be used to fabricate the transistors, and the same applied voltage (from power supply 46) can be used to obliterate the outer carbon nanotubes in all the transistors.

In some applications, it may be preferable for each transistor to have multiple semiconducting carbon nanotubes connected in parallel. FIG. 6, for example, shows a top view of a CNT transistor according to the present invention having four semiconducting CNTs 20 connected in parallel. Each semiconducting CNT has source and drain extensions 36a 36b. An advantage of having multiple nanotubes is that manufacturing yield losses due to metallic conducting central nanotubes will be reduced.

In a microelectronic device having millions of carbon nanotube transistors, it will be important to assure that every transistor has an appropriate applied voltage during the nanotube burnoff (in oxygen) step. In order to assure that proper voltages are applied to every transistor, each source and drain can be connected to tentative voltage supplying networks formed before the device fabrication process. The tentative voltage supplying networks are substantially the same with the voltage supplying networks of conventional large scale integrated circuits. After device fabrication, the tentative voltage source network can be removed partially or completely by conventional etching process once Additionally: redundant circuit design can be employed to mitigate the effect of defective transistor devices.

### BROAD SCOPE OF THE INVENTION

While illustrative embodiments of the invention have been described herein, the present invention is not limited to the various preferred embodiments described herein but includes any and all embodiments having modifications, omissions, combinations (e.g., of aspects across various embodiments), adaptations and/or alterations as would be appreciated by those in the art based on the present disclosure. The limitations in the claims are to be interpreted broadly based on the language employed in the claims and not limited to examples described in the present specification or during the prosecution of the application, which examples are to be construed as non-exclusive. For example, in the present disclosure, the term “preferably” is non-exclusive and means “preferably, but not limited to.” Means-plus-function or step-plus-function limitations will only be employed where for a specific claim limitation all of the following conditions are present in that limitation: a) “means for” or “step for” (i.e., not step of) is expressly recited; b) a corresponding function is expressly recited; and c) structure, material or acts that support that structure are not recited. In this disclosure and during the prosecution of this application, the terminology “present invention” or “invention”, may be used as a reference to one or more aspect within the present disclosure. The language present invention or invention should not be improperly interpreted as an identification of criticality, should not be improperly interpreted as applying across all aspects or embodiments (i.e., it should be understood that the present invention has a number of aspects and embodiments), and should not be improperly interpreted as limiting the scope of the application or claims. In this disclosure and during the prosecution of this application, the terminology “embodiment” can be used to describe any aspect, feature, process or step, any combination thereof, and/or any portion thereof, etc. In some examples, various embodiments may include overlapping features.

What is claimed is:

1. A carbon nanotube (CNT) transistor comprising:
a) a conductive source electrode (source) disposed on a substrate;
b) a conductive drain electrode (drain) disposed on a substrate and spaced apart from the source;
c) a semiconducting CNT having a variable resistance electrically connected between the source and the drain;
d) a conductive gate electrode (gate) disposed proximate to the semiconducting CNT, for controlling the resistance thereof, wherein:
1) a first gap exists between the gate and source,
2) a second gap exists between the gate and drain, and
wherein the semiconducting CNT spans the first and second gaps; and the CNT transistor includes at least one of the following extensions:
e) a conductive source extension extending from the source into the first gap, and at least partially covering the CNT;
f) a conductive drain extension extending from the drain into the second gap, and at least partially covering the CNT.

2. The CNT transistor of claim 1, wherein the source extension and drain extension extend at least half way across the first gap and second gap, respectively.

3. The CNT transistor of claim 1, wherein the source extension and drain extension comprise metal.

4. The CNT transistor of claim 1, wherein the source extension and drain extension comprise “metal carbide”.

5. The CNT transistor of claim 1, wherein the source extension and drain extension comprise metallic-conducting carbon nanotubes surrounding and coaxial with the semiconducting CNT.

6. The CNT transistor of claim 5, wherein the source and drain extensions comprise 1-30 coaxial metallic carbon nanotubes surrounding and coaxial with the semiconducting CNT.

7. The CNT transistor of claim 1, wherein the source extension and drain extension have a width in a Y-direction of less than 5 times a width of the CNT.

8. The CNT transistor of claim 1, wherein the source extension and drain extension have a width in a Y-direction of less than 2 times a width of the CNT.

9. A carbon nanotube (CNT) transistor, comprising:
a) a conductive source electrode (source) disposed on a substrate;
b) a conductive drain electrode (drain) disposed on a substrate;
c) a semiconducting CNT having a variable resistance electrically connected between the source and the drain;
d) a conductive gate electrode (gate) disposed proximate to the semiconducting CNT, for controlling the resistance thereof, wherein:
1) a first gap exists between the gate and source,
2) a second gap exists between the gate and drain,
wherein the semiconducting CNT spans the first and second gaps; and
the CNT transistor includes at least one of the following extensions:
e) a conductive source extension extending from the source into the first gap;
f) a conductive drain extension extending from the drain into the second gap;
wherein the extensions comprise metallic-conducting carbon nanotubes surrounding and coaxial with the semiconducting CNT.

10. The CNT transistor of claim 9, and the source and drain extensions comprise 1-30 metallic carbon nanotubes surrounding and coaxial with the semiconducting CNT.

11. The CNT transistor of claim 9, wherein the source extension and drain extension extend at least half way across the first and second gaps, respectively.

12. A carbon nanotube (CNT) transistor, comprising:
a) a semiconducting CNT electrically connected between a source electrode and a drain electrode;
b) a gate electrode disposed proximate to the semiconducting CNT, for affecting the resistance thereof, wherein the gate electrode is separated from the source and drain electrodes by first and second gaps, respectively;
c) a conductive source extension extending from the source into the first gap;
d) a conductive drain extension extending from the drain into the second gap;
wherein the extensions comprise metallic-conducting carbon nanotubes surrounding and coaxial with the semiconducting CNT.

13. The CNT transistor of claim 12, wherein the source extension and drain extension extend at least half way across the first gap and second gap, respectively.

14. The CNT transistor of claim 12, wherein the source extension and drain extension have a width in a Y-direction of less than 5 times a width of the CNT.

15. The CNT transistor of claim 12, wherein the source extension and drain extension have a width in a Y-direction of less than 2 times a width of the CNT.

16. The CNT transistor of claim 12, wherein, and the source and drain extensions comprise 1-30 coaxial metallic carbon nanotubes surrounding and coaxial with the semiconducting CNT.
